(19) United States
(12) Patent Application Publication
(10) Pub. No.: US 2020/0065270 A1
(43) Pub. Date: Feb. 27, 2020

(54) INDUCTIVE COMPENSATION IN MEMORY SYSTEMS

(71) Applicant: SanDisk Technologies LLC, Addison, TX (US)

(72) Inventors: Md. Sayed Hossain Mobin, San Jose, CA (US); John Thomas Contreras, Palo Alto, CA (US); Pranav Balachander, Santa Clara, CA (US)

(21) Appl. No.: 16/237,018

(22) Filed: Dec. 31, 2018

Related U.S. Application Data
(60) Provisional application No. 62/721,471, filed on Aug. 22, 2018.

(51) Int. Cl. G06F 13/16; G11C 11/409; G06F 12/02; H01L 23/00; G11C 5/02

(52) U.S. Cl. CPC G06F 13/1694; G11C 11/409; H01L 2224/44; H01L 24/42; G11C 5/025; G06F 12/0246

(57) ABSTRACT

An apparatus comprising memory having at least one memory die is disclosed. The apparatus may comprises a memory controller. A data bus is coupled to the controller and the memory. A supplemental inductor is coupled to the data bus.

### CROSS-REFERENCE TO RELATED APPLICATIONS

The present application claims the benefit of U.S. Provisional Patent Application Ser. No. 62/721,471 entitled “INDUCTIVE COMPENSATION IN EMBEDDED APPLICATIONS” filed on Aug. 22, 2018. The foregoing provisional patent application is incorporated by reference as though set forth herein in its entirety.

### TECHNICAL FIELD

The present disclosure, in various embodiments, relates to nonvolatile and/or volatile memory device communications and more particularly relates to inductive compensation and memory systems.

### BACKGROUND

Nonvolatile data storage devices, such as flash solid state memory devices or removable storage cards, have allowed for increased portability of data and software applications. Flash memory devices can enhance data storage density by storing multiple bits in each flash memory cell. For example, Multi-Level Cell (MLC) flash memory devices provide increased storage density by storing 2 bits per cell, 3 bits per cell, 4 bits per cell, or more. Although increasing the number of bits per cell and reducing device feature dimensions may increase a storage density of a memory device, a bit error rate (BER) for data stored at the memory device may also increase.

In a memory device, reflections of signals representing data in a signal pathway can be problematic and result in degradation of the signals. Accordingly, improved techniques, apparatuses and systems for mitigating reflections are desirable.

### BRIEF DESCRIPTION OF THE DRAWINGS

A more particular description is included below with reference to specific embodiments illustrated in the appended drawings. Understanding that these drawings depict only certain embodiments of the disclosure and are not, therefore, to be considered limiting of its scope, the disclosure is described and explained with additional specificity and detail through the use of the accompanying drawings, in which:

FIG. 1 illustrates an embodiment of an array of memory cells including bit and word lines;

FIG. 2 illustrates a diagram of a three-dimensional (3D) memory in a NAND configuration;

FIG. 3 is a schematic block diagram illustrating an embodiment of a 3D vertical memory structure;

FIG. 4 is a block diagram illustrating one embodiment of a nonvolatile storage device;

FIG. 5 is a diagram illustrating one embodiment of a prior art storage system;

FIG. 6 is a circuit diagram illustrating one embodiment of the storage system of FIG. 5;

FIG. 7 is a diagram illustrating one embodiment of an output eye that may be generated by the system of FIG. 5;

FIG. 8 is a diagram illustrating one embodiment of a storage system;

FIG. 9 is a circuit diagram illustrating one embodiment of the storage system of FIG. 8;

FIG. 10 is a diagram illustrating one embodiment of an output eye that may be generated using the system of FIG. 8;

FIG. 11 is a diagram illustrating another embodiment of a storage system; and

FIG. 12 is a diagram illustrating yet another embodiment of a storage system.

### DETAILED DESCRIPTION

Aspects of the present disclosure can be embodied as an apparatus, system, method, or computer program product. Accordingly, aspects of the present disclosure can take the form of an entirely hardware embodiment, an entirely software embodiment (including firmware, resident software, micro-code, or the like) or an embodiment combining software and hardware aspects that can all generally be referred to herein as a “circuit,” “module,” “apparatus,” or “system.” Furthermore, aspects of the present disclosure can take the form of a computer program product embodied in one or more non-transitory computer-readable storage media storing computer-readable and/or executable program code.

Many of the functional units described in this specification have been labeled as modules in order to more particularly emphasize their implementation independence. For example, a module can be implemented as a hardware circuit comprising custom VLSI circuits or gate arrays, off-the-shelf semiconductors such as logic chips, transistors, or other discrete components. A module can also be implemented in programmable hardware devices such as field programmable gate arrays, programmable array logic, programmable logic devices, or the like.

Modules can also be implemented at least partially in software for execution by various types of processors. An identified module of executable code can, for instance, comprise one or more physical or logical blocks of computer instructions which can, for instance, be organized as an object, procedure, or function. Nevertheless, the executables of an identified module need not be physically located together but can comprise disparate instructions stored in different locations which, when joined logically together, comprise the module and achieve the stated purpose for the module.

Indeed, a module of executable code can include a single instruction, or many instructions, and can even be distributed over several different code segments, among different programs, across several memory devices, or the like. Where a module or portions of a module are implemented in software, the software portions can be stored on one or more computer-readable and/or executable storage media. Any combination of one or more computer-readable storage media can be utilized. A computer-readable storage medium can include, for example, but not limited to, an electronic, magnetic, optical, electromagnetic, infrared, or semiconductor system, apparatus, or device, or any suitable combination of the foregoing, but would not include propagating signals. In the context of this document, a computer-readable and/or executable storage medium can be any tangible and/or non-transitory medium that can contain or store a program for use by or in connection with an instruction execution system, apparatus, processor, or device.

Computer program code for carrying out operations for aspects of the present disclosure can be written in any combination of one or more programming languages, including an object oriented programming language such as Python, Java, Smalltalk, C++, C#, Objective C, or the like, conventional procedural programming languages, such as the “C” programming language, scripting programming languages, and/or other similar programming languages. The program code can execute partly or entirely on one or more of a user's computer and/or on a remote computer or server over a data network or the like.

A component, as used herein, comprises a tangible, physical, non-transitory device. For example, a component can be implemented as a hardware logic circuit comprising custom VLSI circuits, gate arrays, or other integrated circuits; off-the-shelf semiconductors such as logic chips, transistors, or other discrete devices; and/or other mechanical or electrical devices. A component can also be implemented in programmable hardware devices such as field programmable gate arrays, programmable array logic, programmable logic devices, or the like. A component can comprise one or more silicon integrated circuit devices (e.g., chips, die, die planes, packages) or other discrete electrical devices, in electrical communication with one or more other components through electrical lines of a printed circuit board (PCB) or the like. Each of the modules described herein, in certain embodiments, can alternatively be embodied by or implemented as a component.

A circuit, as used herein, comprises a set of one or more electrical and/or electronic components providing one or more pathways for electrical current. In certain embodiments, a circuit can include a return pathway for electrical current, so that the circuit is a closed loop. In another embodiment, however, a set of components that do not include a return pathway for electrical current can be referred to as a circuit (e.g., an open loop). For example, an integrated circuit can be referred to as a circuit regardless of whether the integrated circuit is coupled to ground (as a return pathway for electrical current) or not. In various embodiments, a circuit can include a portion of an integrated circuit, an integrated circuit, a set of integrated circuits, a set of non-integrated electrical and/or electrical components with or without integrated circuit devices, or the like. In an embodiment, a circuit can include: custom VLSI circuits, gate arrays, logic circuits, or other integrated circuits; off-the-shelf semiconductors such as logic chips, transistors, or other discrete devices; and/or other mechanical or electrical devices. A circuit can also be implemented as a synthesized circuit in a programmable hardware device such as field programmable gate array, programmable array logic, programmable logic device, or the like (e.g., as firmware, a netlist, or the like). A circuit can comprise one or more silicon integrated circuit devices (e.g., chips, die, die planes, packages) or other discrete electrical devices, in electrical communication with one or more other components through electrical lines of a printed circuit board (PCB) or the like. Each of the modules described herein, in certain embodiments, can be embodied by or implemented as a circuit.

By way of introduction, the following brief definitions are provided for various terms used in this application. Additional definitions will be provided in the context of the discussion of the figures herein. As used herein, “exemplary” can indicate an example, an implementation, and/or an aspect, and should not be construed as limiting or as indicating a preference or a preferred implementation. Further, it is to be appreciated that certain ordinal terms (e.g., “first” or “second”) can be provided for identification and ease of reference and may not necessarily imply physical characteristics or ordering. Therefore, as used herein, an ordinal term (e.g., “first,” “second,” “third”) used to modify an element, such as a structure, a component, an operation, etc., does not necessarily indicate priority or order of the element with respect to another element, but rather distinguishes the element from another element having a same name (but for use of the ordinal term). In addition, as used herein, indefinite articles (“a” and “an”) can indicate “one or more” rather than “one.” As used herein, a structure or operation that “comprises” or “includes” an element can include one or more other elements not explicitly recited. Thus, the terms “including,” “comprising,” “having,” and variations thereof signify “including but not limited to” unless expressly specified otherwise. The terms “a,” “an,” and “the” also refer to “one or more” unless expressly specified otherwise. Further, an operation performed “based on” a condition or event can also be performed based on one or more other conditions or events not explicitly recited. As used in this application, the terms “an embodiment,” “one embodiment,” “another embodiment,” or analogous language do not refer to a single variation of the disclosed subject matter; instead, this language refers to variations of the disclosed subject matter that can be applied and used with a number of different implementations of the disclosed subject matter. An enumerated listing of items does not imply that any or all of the items are mutually exclusive and/or mutually inclusive, unless expressly specified otherwise.

Aspects of the present disclosure are described below with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions can be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

It should also be noted that, in some alternative implementations, the functions noted in the block can occur out of the order noted in the figures. For example, two blocks shown in succession can, in fact, be executed substantially concurrently, or the blocks can sometimes be executed in the reverse order, depending upon the functionality involved. Other steps and methods can be conceived that are equivalent in function, logic, or effect to one or more blocks, or portions thereof, of the illustrated figures. Although various arrow types and line types can be employed in the flowchart and/or block diagrams, they are understood not to limit the scope of the corresponding embodiments. For instance, an arrow can indicate a waiting or monitoring period of unspecified duration between enumerated steps of the depicted embodiment.

In the following detailed description, reference is made to the accompanying drawings, which form a part thereof. The foregoing summary is illustrative only and is not intended to be in any way limiting. In addition to the illustrative aspects, embodiments, and features described above, further aspects, embodiments, and features will become apparent by reference to the drawings and the following detailed description. The description of elements in each figure can refer to elements of proceeding figures. Like numbers can refer to like elements in the figures, including alternate embodiments of like elements.

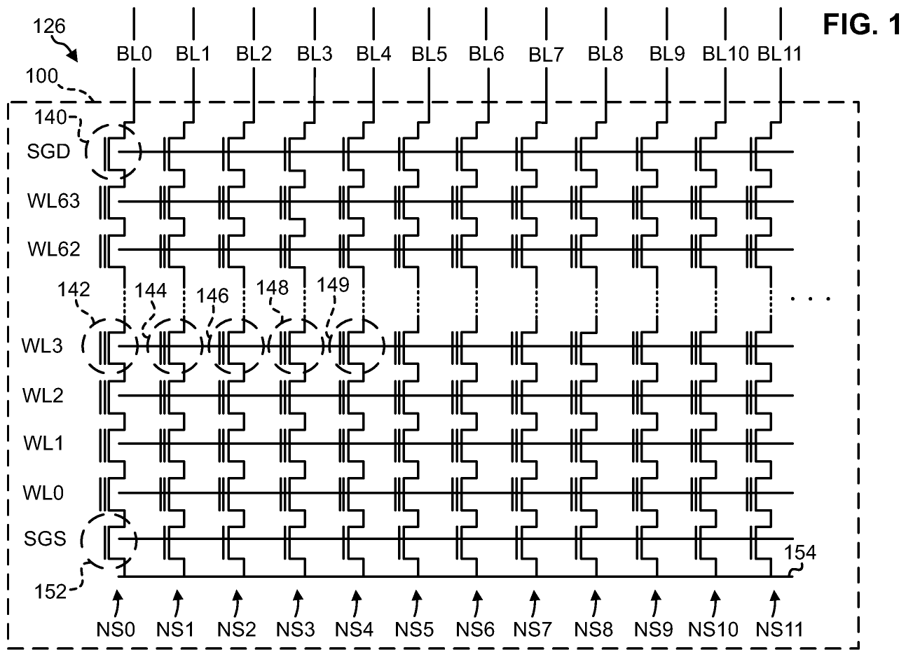

FIG. 1 depicts an embodiment of memory arranged as NAND flash memory cells in a memory array 126. As used herein, the term “memory” denotes semiconductor memory. Types of semiconductor memory include volatile memory and nonvolatile memory. Nonvolatile memory allows information to be stored and retained even when the nonvolatile memory is not connected to a source of power (e.g., a battery). Examples of nonvolatile memory include flash memory (e.g., NAND-type and NOR-type flash memory), Electrically Erasable Programmable Read-Only Memory (EEPROM), ferroelectric memory (e.g., FeRAM), magnetoresistive memory (e.g., MRAM), spin-transfer torque magnetic random access memory (STT-RAM or STT-MRAM), resistive random access memory (e.g., ReRAM or RRAM) and phase change memory (e.g., PRAM or PCM). Nonvolatile memory includes one or more memory cells. As used herein, the term “NAND flash memory” is a type of nonvolatile flash memory that employs NAND-type logic gates to store data. NAND flash memory encompasses, for example, both 2D and 3D NAND flash memory. A “memory cell” is an electronic device or component capable of storing electronic information. In an embodiment, nonvolatile memory utilizes floating-gate transistors or charge trap transistors as memory cells. The ability to adjust the threshold voltage of a floating-gate transistor or charge trap transistor allows the transistor to act as a nonvolatile storage element or memory cell, such as a single-level cell (SLC). However, in some cases more than one data bit per memory cell (e.g., a multi-level cell) can be provided by programming and reading multiple threshold voltages or threshold voltage ranges, including a multi-level cell (MLC) (2 bits-per-cell), a triple-level cell (TLC) (3 bits-per-cell), a quad-level cell (QLC) (4 bits-per-cell), and so forth.

The memory array 126 can include many blocks of memory. A “block of memory” is a set of memory cells. For example, a block of memory (e.g., an array of memory cells) includes memory cells arranged in word lines and bit lines. A “sub-block” of memory is a subset of a block of memory. For instance, a sub-block is a subset of memory cells corresponding to a subset of the word lines of a block of memory. In an embodiment, a sub-block includes fifty word lines in a block of memory, where the block of memory includes more than fifty word lines. A sub-block can denote a physical sub-block, a logical sub-block, or both. A block of memory includes two or more sub-blocks. In an embodiment, memory is structured as two-dimensional (2D) NAND. In another embodiment, memory is structured as three-dimensional (3D) NAND. In an embodiment, one or more of the components described herein (e.g., memory die, memory, block, sub-block, memory cells, circuits, controllers, and/or nonvolatile storage systems) are implemented with one or more elements (e.g., transistors, resistors, capacitors, inductors, and/or conductors) in integrated circuitry.

An illustrative block of memory (or block) 100, as shown in FIG. 1, includes a number of NAND strings NS0 to NS11 and respective bit lines (e.g., BL0 to BL11, which are shared among the blocks). Each NAND string is connected at one end to a drain select gate (SGD), and the control gates of the drain select gates are connected via a common SGD line. Each NAND string is connected at its other end to a source select gate (SGS) which, in turn, is connected to a common source line 154. For example, NS0 includes a source side select gate transistor 152 and a drain side select gate transistor 140. Example storage elements 142, 144, 146, 148, and 149 are in NS0 to NS4, respectively, and are connected to a word line WL3. For example, WL3 could be a selected word line which is selected for programming and the example storage elements can be selected storage elements which are selected for programming. Other storage elements connected to WL3 can also be selected storage elements. Sixty-four word lines, for example, WL0-WL63, extend between the source-side select gates and the drain-side select gates.

Other types of nonvolatile memory in addition to NAND flash memory can also be used. For example, another type of memory cell useful in flash EEPROM systems utilizes a nonconductive dielectric material in place of a conductive floating gate to store charge in a nonvolatile manner. In an embodiment, triple layer dielectric formed of silicon oxide, silicon nitride, and silicon oxide (ONO) is sandwiched between a conductive control gate and a surface of a semi-conductive substrate above the memory cell channel. The cell is programmed by injecting electrons from the cell channel into the nitride, where they are trapped and stored in a limited region. This stored charge then changes the voltage level of a portion of the channel of the cell in a manner that is detectable. The cell is erased by injecting hot holes into the nitride. A similar cell can be provided in a split-gate configuration where a doped polysilicon gate extends over a portion of the memory cell channel to form a separate select transistor. Another type of memory uses a metallic (conductive) charge storage element in a NAND architecture.

In another approach, NROM cells are used. Two bits, for example, are stored in each NROM cell, where an ONO dielectric layer extends across the channel between source and drain diffusions. The charge for one data bit is localized in the dielectric layer adjacent to the drain, and the charge for the other data bit is localized in the dielectric layer adjacent to the source. Multi-state data storage is obtained by separately reading binary states of the spatially separated charge storage regions within the dielectric. Other types of nonvolatile memory are also known. In an alternative embodiment, resistance levels rather than threshold voltage levels can be stored and sensed.

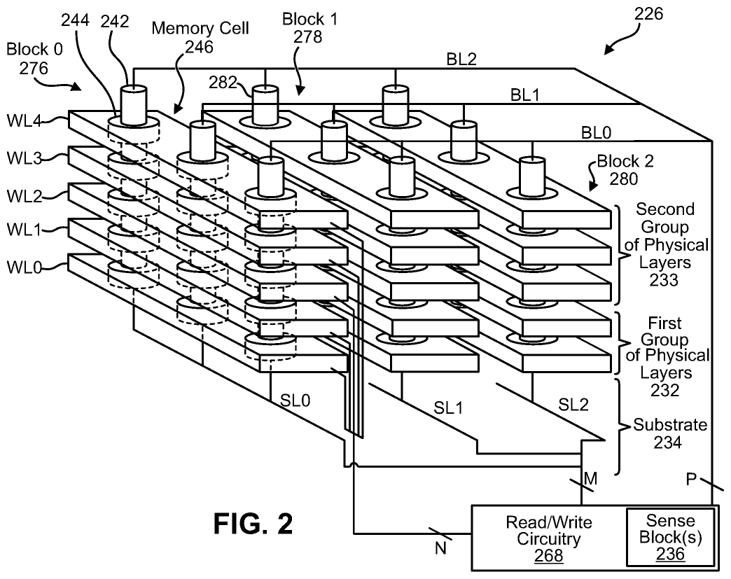

FIG. 2 illustrates an embodiment of 3D memory 226 in a NAND flash configuration. The 3D memory 226 includes multiple physical layers that are monolithically formed above a substrate 234, such as a silicon substrate. Storage elements (e.g., memory cells), such as a representative memory cell 246, are arranged in arrays in the physical layers.

The representative memory cell 246 includes a charge trap structure 244 between a word line/control gate WL4 and a conductive channel 242. Charge can be injected into or drained from the charge trap structure 244 via biasing of the conductive channel 242 relative to the word line WL4. For example, the charge trap structure 244 can include silicon nitride and can be separated from the word line WL4 and the conductive channel 242 by a gate dielectric, such as a silicon oxide. An amount of charge in the charge trap structure 244 affects an amount of current through the conductive channel 242 during a read operation of the memory cell 246 and indicates one or more bit values that are stored in the memory cell 246.

The 3D memory 226 includes multiple erase blocks, including a first block (block 0) 276, a second block (block 1) 278, and a third block (block 2) 280. Each block 276, 278, 280 includes a “vertical slice” of the physical layers that includes a stack of word lines, illustrated as a first word line WL0, a second word line WL1, a third word line WL2, a fourth word line WL3, and a fifth word line WL4. Multiple conductive channels (having a substantially vertical orientation, as shown in FIG. 2) extend through the stack of word lines. Each conductive channel is coupled to a storage element in each word line WL0-WL4, forming a NAND string of storage elements. FIG. 2 illustrates three blocks 276, 278, 280, five word lines WL0-WL4 in each block 276, 278, 280, and three conductive channels in each block 276, 278, 280 for clarity of illustration. However, the 3D memory 226 can have more than three blocks, more than five word lines per block, and more than three conductive channels per block.

Read/write circuitry 268 is coupled to the conductive channels via multiple conductive lines, illustrated as a first bit line BL0, a second bit line BL1, and a third bit line BL2 at a first end of the conductive channels (e.g., an end most remote from the substrate 234) and a first source line SL0, a second source line SL1, and a third source line SL2 at a second end of the conductive channels (e.g., an end nearer to or within the substrate 234). The read/write circuitry 268 is illustrated as coupled to the bit lines BL0-BL2 via “P” control lines, coupled to the source lines SL0-SL2 via “M” control lines, and coupled to the word lines WL0-WL4 via “N” control lines. Each of P, M, and N can have a positive integer value based on the specific configuration of the 3D memory 226. In the example shown in FIG. 2, P=3, M=3, and N=5.

In a particular embodiment, each of the bit lines BL0-BL2 and each of the source lines SL0-SL2 can be coupled to the same end (e.g., the first end or the second end) of different conductive channels. For example, a particular bit line BL0-BL2 can be coupled to a first end of a conductive channel 282 and a particular source line can be coupled to a first end of the conductive channel 242. A second end of the conductive channel 282 can be coupled (e.g., electrically coupled) to a second end of the conductive channel 242. Accordingly, the conductive channel 282 and the conductive channel 242 can be coupled in series and can be coupled to the particular bit line BL0-BL2 and the particular source line SL0-SL2, each of which is coupled to a particular NAND string.

Although each of the conductive channels, such as the conductive channels 242, 282, is illustrated as a single conductive channel, each of the conductive channels can include multiple conductive channels that are in a stack configuration. The multiple conductive channels in a stacked configuration can be coupled by one or more connectors. Additionally, an etch stop layer (not illustrated in FIG. 2) having a conductive connector coupled to physically proximate portions of a conductive channel can be included in the multiple conductive channels, such as between the first group of physical layers 232 and the second group of physical layers 233. Additionally, or alternatively, one or more sub-block gate transistors (not illustrated in FIG. 2) can be coupled between the first group of physical layers 232 and the second group of physical layers 233.

In an embodiment, the first group of physical layers 232 is an example of a first sub-block and the second group of physical layers 233 is an example of a second sub-block. For example, each sub-block (e.g., “word line-based” sub-blocks) can include memory cells corresponding to a subset of word lines WL0-WL4. In an alternative embodiment, each sub-block (e.g., “string-based” sub-blocks) can include memory cells corresponding to a subset of strings (e.g., NAND strings), and can have, for example, common source lines SL0-SL2, but not common bit lines BL0-BL2, or vice versa.

The read/write circuitry 268 facilitates and/or effectuates read and write operations performed on the 3D memory 226. For example, data can be stored to storage elements coupled to a word line WL0-WL4 and the read/write circuitry 268 can read bit values from the storage elements (e.g., memory cells) using one or more sense blocks 236. As another example, the read/write circuitry 268 can apply selection signals to control lines coupled to the word lines WL0-WL4, the bit lines BL0-BL2, and the source lines SL0-SL2 to cause a programming voltage (e.g., a voltage pulse or series of voltage pulses) to be applied across selected storage element(s) of the selected word line (e.g., the fourth word line WL4).

The read/write circuitry 268 includes one or more sense blocks 236. The sense blocks 236 are utilized to read or sense one or more values stored in a memory cell. In one approach, one sense block 236 is provided for a group of NAND strings, each of which is coupled to a particular bit line BL0-BL2. For example, a sense block 236 is associated with BL0. Another sense block 236 is associated with BL1, and yet another sense block 236 is associated with BL2. Each sense block 236 can include a memory controller (not illustrated in FIG. 2). Each sense block 236 also includes a sense module for each NAND string. Alternatively, a sense block 236 can be coupled to an interval of bit lines, such as even or odd numbered bit lines.

During a read operation, a controller can receive a request from a host device, such as a computer, smartphone, or laptop computer. The controller can cause the read/write circuitry 268 to read bits from particular storage elements of the 3D memory 226 by applying appropriate signals to the control lines to cause storage elements of a selected word line to be sensed. Accordingly, the 3D memory 226 having multiple conductive channels in a stacked configuration can be configured to read from and write data to one or more storage elements.

One or more subblocks of memory cells 246 in an array of memory cells 246 can be coupled by a channel (e.g., a physical communication channel). In an embodiment, the channel comprises a bit line BL0-BL2 and/or a source line SL0-SL2.

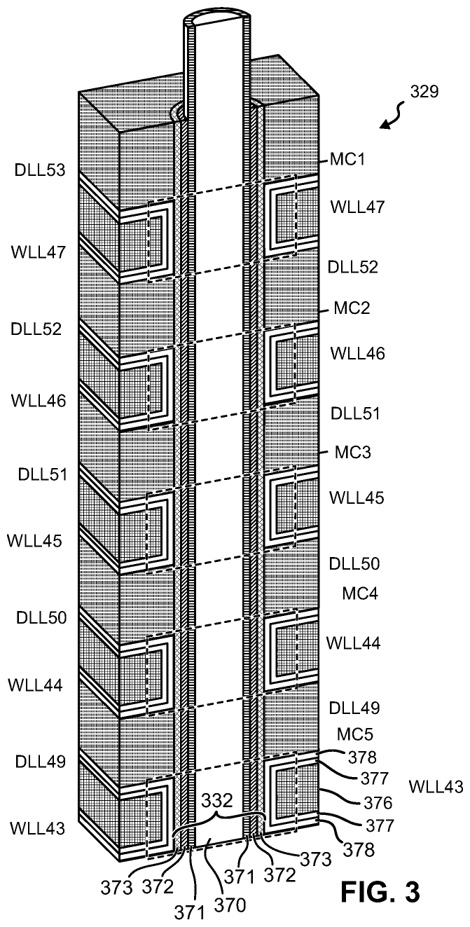

FIG. 3 illustrates one embodiment of a cross-sectional view of a 3D, vertical memory structure or string 329. In one embodiment, the vertical column 332 is round and includes four layers; however, in other embodiments more or less than four layers can be included, and other shapes can be used (e.g., a “U” shape instead of an “I” shape or the like). In one embodiment, a vertical column 332 includes an inner core layer 370 that is made of a dielectric, such as SiO2. Other materials can also be used. Surrounding the inner core or inner core layer 370 is a polysilicon channel 371. Materials other than polysilicon can also be used. Note that it is the channel 371 that connects to the bit line. Surrounding the channel 371 is a tunneling dielectric 372. In one embodiment, the tunneling dielectric 372 has an ONO structure. Surrounding the tunneling dielectric 372 is a shared charge-trapping layer 373, such as (for example) Silicon Nitride. Other materials and structures can also be used. The technology described herein is not limited to any particular material or structure.

FIG. 3 depicts dielectric layers DLL49, DLL50, DLL51, DLL52, and DLL53, as well as word line layers WLL43, WLL44, WLL45, WLL46, and WLL47. Each of the word line layers includes a word line region 376 surrounded by an aluminum oxide layer 377, which is surrounded by a blocking oxide (SiO2) layer 378. The physical interaction of the word line layers with the vertical column 332 forms the memory cells. Thus, a memory cell, in one embodiment, comprises the channel 371, tunneling dielectric 372, charge-trapping layer 373 (e.g., shared with other memory cells), blocking oxide layer 378, aluminum oxide layer 377, and the word line region 376. In some embodiments, the blocking oxide layer 378 and aluminum oxide layer 377 can be replaced by a single layer of material with insulating properties or by more than two layers of different material with insulating properties. Furthermore, the materials used are not limited to silicon dioxide (SiO2) or aluminum oxide. For example, word line layer WLL47 and a portion of vertical column 332 comprise a memory cell MC1. Word line layer WLL46 and a portion of vertical column 332 comprise a memory cell MC2. Word line layer WLL45 and a portion of vertical column 332 comprise a memory cell MC3. Word line layer WLL44 and a portion of vertical column 332 comprise a memory cell MC4. Word line layer WLL43 and a portion of vertical column 332 comprise a memory cell MC5. In other architectures, a memory cell can have a different structure, however, the memory cell would still be the storage unit.

When a memory cell is programmed, electrons are stored in a portion of the charge-trapping layer 373 that is associated with the memory cell. These electrons are drawn into the charge-trapping layer 373 from the channel 371, through the tunneling dielectric 372, in response to an appropriate voltage on the word line region 376. The threshold voltage (Vt) of a memory cell is increased in proportion to the amount of stored charge. In one embodiment, the programming is achieved through Fowler-Nordheim tunneling of the electrons into the charge-trapping layer. During an erase operation, the electrons return to the channel or holes are injected into the charge-trapping layer to recombine with electrons. In one embodiment, erasing is achieved using hole injection into the charge-trapping layer via a physical mechanism such as gate induced drain leakage (GIDL).

Storage cells in the same location or position in different memory structures 329 (e.g., different memory strings 329) on different bit lines, in certain embodiments, can be on the same word line. Each word line can store one page of data, such as when 1-bit of data is stored per cell (SLC); two pages of data, such as when 2-bits of data are stored per cell (MLC); three pages of data, such as when 3-bits of data are stored per cell (TLC); four pages of data, such as when 4-bits of data are stored per cell (QLC); or another number of pages of data.

In the depicted embodiment, a vertical, 3D memory structure 329 comprises an “I” shaped memory structure 329. In other embodiments, a vertical, 3D memory structure 329 can comprise a “U” shaped structure or can have another vertical and/or stacked architecture. In certain embodiments, four sets of strings 329 (e.g., four sets of 48 word lines, or another predefined number of word lines) can form an erase block, while in other embodiments, fewer or more than four sets of strings 329 can form an erase block. As can be appreciated, any suitable number of storage cells can be part of a single string 329. In one embodiment, a single string 329 includes 48 storage cells.

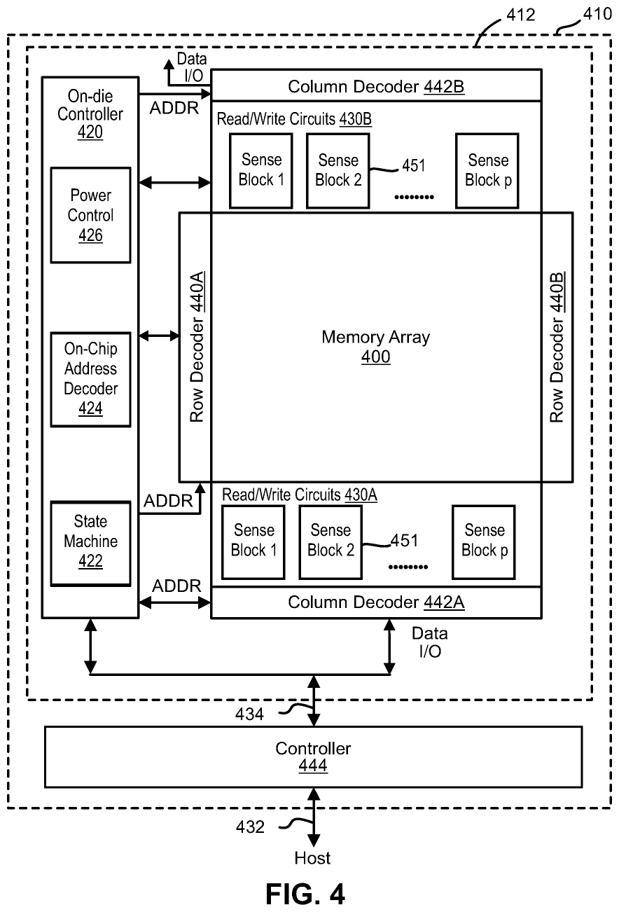

FIG. 4 is a schematic block diagram illustrating an embodiment of a nonvolatile storage device 410. The nonvolatile storage device 410 can include one or more memory die or chips 412. A “memory die” comprises a block of semiconducting material on which a memory circuit is fabricated and, as used herein, also includes the memory circuit disposed thereon.

The memory die 412, in some embodiments, includes an array 400 (e.g., two-dimensional or three dimensional) of memory cells, an on-die controller 420, and read/write circuits 430A/430B. In one embodiment, access to the memory array 400 by the various peripheral circuits is implemented in a symmetric fashion, on opposite sides of the memory array 400, so that the densities of access lines and circuitry on each side are reduced by half. The read/write circuits 430A/430B, in a further embodiment, include multiple sense blocks 451 which allow a page of memory cells to be read or programmed in parallel.

The memory array 400, in various embodiments, is addressable by word lines via row decoder circuits 440A/440B and by bit lines via column decoder circuits 442A/442B. In some embodiments, a controller 444 is included in the same memory device 410 (e.g., a removable storage card or package) as the one or more memory die 412. Commands and data are transferred between the host and controller 444 via lines 432 and between the controller and the one or more memory die 412 via lines 434. One implementation can include multiple chips 412.

On-die controller 420, in one embodiment, cooperates with the read/write circuits 430A/430B to perform memory operations on the memory array 400. The on-die controller 420, in certain embodiments, includes a state machine 422, an on-chip address decoder 424, and a power control circuit 426. In one embodiment, the on-chip address decoder 424 and/or the power control circuit 426 can be part of and/or controlled by the controller 444.

The state machine 422, in one embodiment, provides chip-level control of memory operations. The on-chip address decoder 424 provides an address interface to convert between the address that is used by the host or a memory controller to the hardware address used by the decoder circuits 440A, 440B, 442A, 442B. The power control circuit 426 controls the power and voltages supplied to the word lines and bit lines during memory operations. In one embodiment, the power control circuit 426 includes one or more charge pumps that can create voltages larger than the supply voltage.

In one embodiment, one or any combination of the on-die controller 420, state machine 422, power control circuit 426, on-chip address decoder 424, decoder circuit 442A, decoder circuit 442B, decoder circuit 440A, decoder circuit 440B, read/write circuits 430A, read/write circuits 430B, and/or controller 444 can be referred to as one or more managing circuits.

The nonvolatile storage device 410 illustrated in FIG. 4 may be employed, for example, with a computing device, such as a desktop computer, a server, laptop computer, tablet, or smartphone. In addition, the nonvolatile storage device 410 may comprise a portion of a portable storage unit, which may engage with a computing device using a universal serial bus interface (USB) or other types of interface.

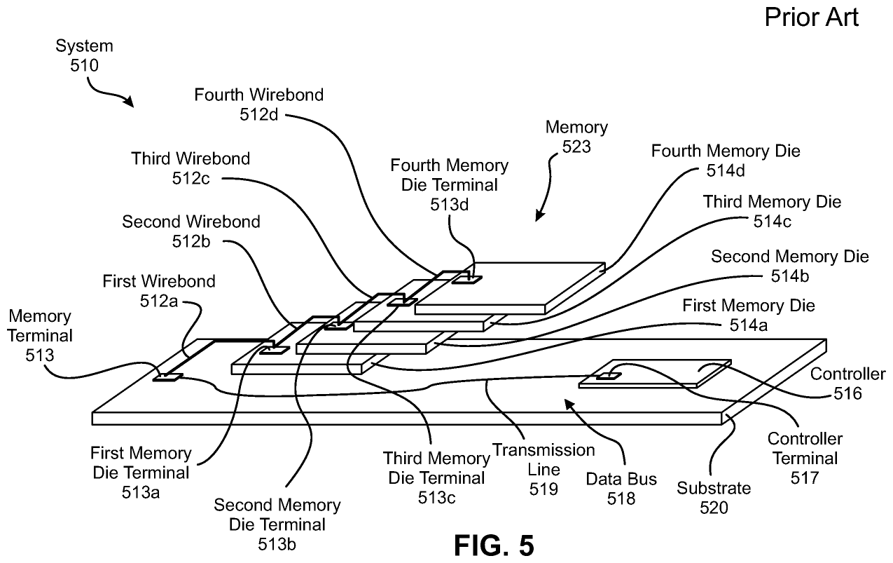

FIG. 5 is a block diagram illustrating one embodiment of a storage system 510. The system 510 may comprise an embedded system. As used herein, an “embedded system” comprises a system having a processor (such as a microprocessor, controller, ASIC, FPGA, etc.) designed to perform specific function(s) in contrast to a general-purpose system, which can be configured to perform many different functions. As used herein, an “embedded system” comprises a unitary system that does not have user removable or user serviceable components. Embedded systems often comprise part of a larger mechanical or electrical system. One example of an embedded system is designed and functions to retrieve stored data from a memory, as illustrated in FIG. 5. Embedded systems are frequently, but not always, positioned on a unitary substrate.

The system 510 illustrated in FIG. 5 comprises a substrate 520. As used herein, a “substrate” comprises any structure that provides support for other components, such as a controller 516, memory 523 or a transmission line 519. A substrate, for example, may be planar in shape and may be formed, for example, of silicon, silicon dioxide, aluminum oxide, sapphire, germanium, gallium arsenide (GaAs), an alloy of silicon and germanium, or indium phosphide (InP).

As illustrated in FIG. 5, The substrate 520 provides support and secures components positioned thereon, such as the controller 516 and the memory 523. In addition, communication channels, such as the transmission line 519, may pass on top of or may be disposed entirely or partially within the substrate.

A controller 516 and memory 523 are positioned on the substrate 520. The terms “memory” and “controller” have been defined above. The memory 523 illustrated in FIG. 5 comprises a first, second, third and fourth memory die 514a-d. Of course, the memory 523 could include a different number of memory dies, such as eight or sixteen memory dies.

The memory dies 514a-d, as illustrated in FIG. 5, are serially coupled using a plurality of wire bonds 512a-d. In an alternative embodiment, the memory dies 514a-d are coupled in parallel. As used herein, the wire bonds 512a-b themselves comprise wires, often made of aluminum, alloyed aluminum, copper, silver, gold or doped gold. The wire bonds 512a-d are often 500 μm or greater. The number of wire bonds 512a-d may vary with the number of memory dies 514a-d in the memory 523.

Wire bonds 512a-d are frequently used to interconnect integrated circuits (e.g., memory dies 514a-d). Wire bonds 512a-d may also be used to interconnect communication channels or components on a substrate 520 (e.g., a printed circuit board) to an integrated circuit. Wire bonds 512a-d may employ a contact pad, often made from gold, through which the wire bonds 512a-d are coupled to an integrated circuit. In this application, the contact pad may be referred to as a memory die terminal 513a-d.

As used herein, a “terminal” comprising a beginning or end of a particular component and may comprise a connection point for a particular component. For example, as used herein, a “memory terminal” comprises a connection point for memory or a memory die, such as the memory terminal 513 or the first, second, third or fourth memory die terminal 513a-d.

As used herein, “wire bonds” refers wires, often made of aluminum, alloyed aluminum, copper, silver, gold or doped gold, for interconnection of integrated circuits and/or communication channels. The number of wire bonds 512a-d may vary with the number of memory dies 514a-d in the memory 523.

As used herein, the term “coupled” signifies a direct or indirect connection enabling electrical communication between two items. A direct connection involves two components physically contacting one another or separated only by one or more connectors, such as a contact pad(s), terminal(s), wire(s) or coupler(s). An indirect connection involves two components that are in electrical communication but are separated by one or more discrete components, such as a resistor, transistor, or capacitor. As used herein, “serially coupled” signifies that components are connected in series, i.e., one after another to a common communication channel or set of communication channels.

Components, in contrast, are “coupled in parallel” when there is an independent communication channel for each pertinent component.

As used herein, a “controller” or “memory controller” comprises any type of processor that operates or aids in the retrieval or storage of data. One example of a “controller” or “memory controller” is an application-specific integrated circuit (ASIC) processor. The “controller” or “memory controller” may comprise, for example, a system controller for controlling a solid-state drive (SSD). The controller 516 may control, for example, the storage and retrieval of data stored in memory 523.

The controller 516 is in electrical communication with the memory 523 via a data bus 518. The controller 516 may also be referred to as a memory controller 516. The data bus 518 communicates signals representing data and/or control signals between the controller 516 and the memory 523. The data bus 518 may comprise, for example, a transmission line 519 positioned on the substrate 520, the memory terminal 513, and a plurality of wire bonds 512a-d. As used herein, the term “positioned on” signifies that the component at issue is physically disposed on top of (e.g., such as on top of the substrate 520) or may be partially or entirely disposed within (e.g., such as being partially or entirely disposed within the substrate 520). A “data bus,” as used herein, signifies a communication channel through which data (e.g., data retrieved from a memory 523 or to be stored on the memory 523) may be transmitted between two components, such as between the controller 516 and the memory 523. A “data bus” may also be used to communicate control signals employed in connection with the storage and retrieval of the data.

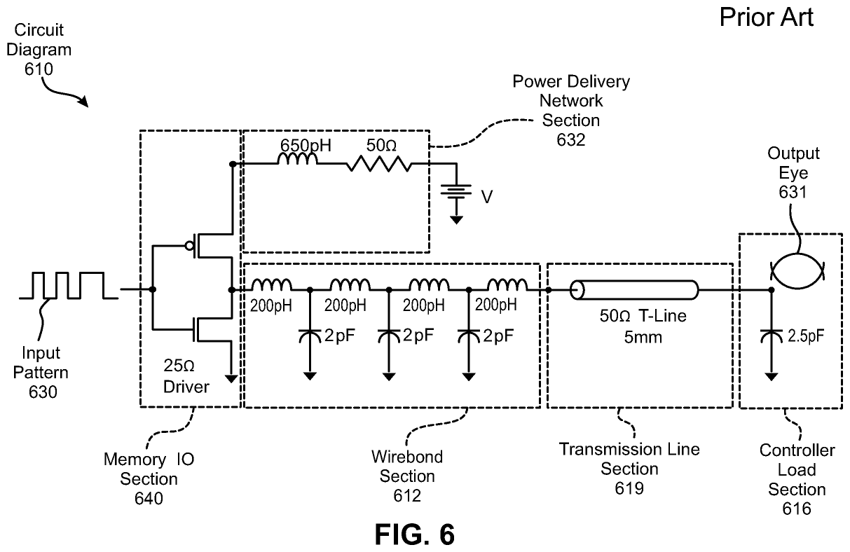

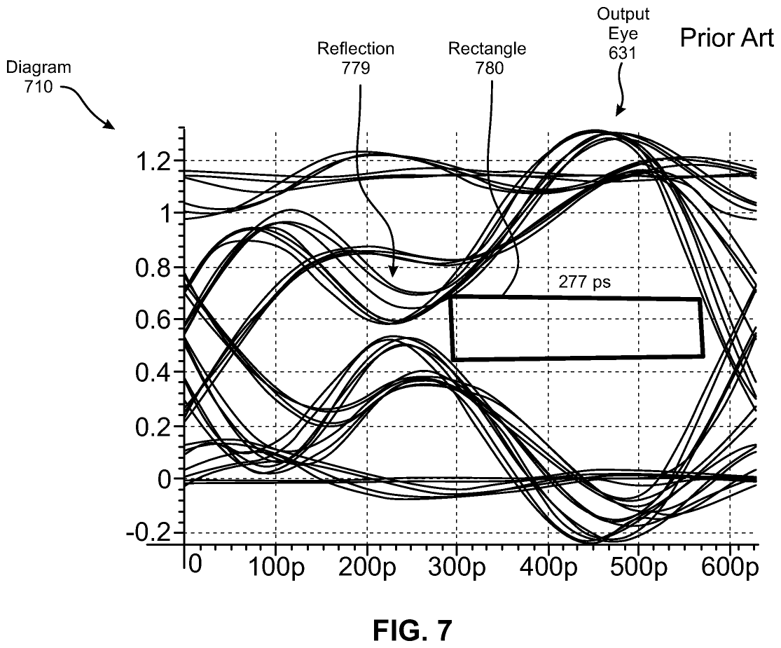

FIG. 6 is one embodiment of a circuit diagram 610 of the system 510 of FIG. 5. As illustrated, the circuit diagram 610 may comprise a memory input/output section 640, wire bond section 612, a transmission line section 619, controller load section 616 and a power delivery network section 632. The memory input/output section 640 may comprise, for example, a 25 ohm (S2) memory driver. As illustrated, each wire bond 512a-d represented in the wire bond section 612 comprises 200 picohenries (pH) of inductance, while each memory pin cap comprises 2 picofarads (pF) of capacitance. The transmission line section 619 may, for example, comprise 50 ohms of impedance for a transmission line 519 that is 5 mm in length. The controller load section 616 indicates that a controller pin cap has 2.5 pF of capacitance. The power delivery network section 632 comprises a capacitor of 650 pH and a serially coupled resistor of 50 ohms. A voltage level provided to the system 510 is represented by the letter “V.” An output eye 631 is generated by the system 510 in response to the input pattern 630, as will be discussed further in connection with FIG. 7. It should be noted that the specific components provided in FIG. 6 are merely illustrative and not limiting of the claimed subject matter, as is the case with figures included in this application.

FIG. 7 is a diagram 710 of a simulation of an output eye 631 based on the assumptions of the circuit diagram 610 of FIG. 6 with a data rate at 1600 Mbps (800 MHz). The output eye 631—also referred to as an eye pattern or simply an “eye”—represents an oscilloscope display of the output eye 631 generated by the system 510 based on the input pattern 630. The vertical axis represents power (with “1” representing a binary one and “0” representing a binary zero), while the horizontal axis represents time in picoseconds. As illustrated in the diagram 710, the output eye 631 is substantially occluded by reflection 779. A rectangle 780 represented in the diagram 710 shows the valid length of the output eye 631 of only 277 ps. The reflection 779 thus occludes the eye-opening, which would cause significant data degradation.

In one embodiment, the reflections are due to the short length of the transmission line 519 (e.g., 5 mm) and the low impedance of the wire bond structure at higher transmission speeds (e.g., 1200 megabits per second (Mbps) at 600 Hz or greater). The wire bond structure comprises both the wire bonds 512a-d and associated pin caps. The pin caps may comprise a memory input output pin cap (which may comprise a portion of the memory 10 (Input/Output) section 604) and contact caps for each memory die 514a-d (e.g., memory die terminals 513a-d). The wire bond structure may include multiple ground wire bonds (i.e., wire bond connection(s) to ground) and also power wire bonds (i.e., wire bond connection(s) to power), which are not illustrated in the figures. These multiple ground wire bonds effectively reduce the ground inductance with the total inductance being represented in the transmission line. For simplicity, FIGS. 5, 6, 8, 9, 11, and 12 illustrate a single wire bond structure, but these embodiments may also include, for example, multiple ground wire bonds, multiple power wire bonds, and may also include multiple wire bond bus connections (e.g., an 8-bit 10 bus, which includes, for example, eight wire bonds between each memory die).

Reflection may be mitigated or eliminated by adding on-die termination (ODT)—such as 50 ohms—at the controller load section 616. While this mechanism can produce a significant opening of the eye, the direct-current power dissipation resulting from such a solution is significant. This power dissipation may be unacceptable in many portable applications, such as in cellular phones.

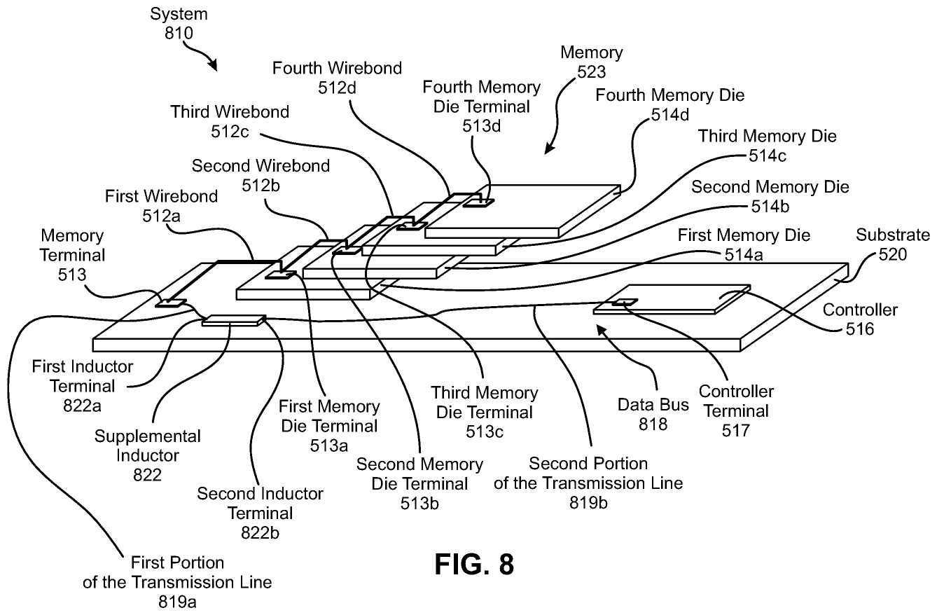

FIG. 8 illustrates a system 810 comprising a supplemental inductor 822 and, more specifically, a discrete inductor 822. The discrete inductor 822 mitigates reflection, while avoiding the power dissipation associated with ODT. The system 810 may comprise, for example, an embedded system. The system 810 may comprise an embedded system. As indicated in FIG. 8, the system 810 comprises a substrate 520.

As illustrated in FIG. 8, the controller 516 is positioned on the substrate 520. As indicated above, the controller 516 controls, for example, the storage and retrieval of data stored in the memory 523. Of course, the controller 516 may perform other functions depending on the particular purpose or function for which the system 810 is designed. By way of example only, the controller 516 may be a general-purpose processor.

The memory 523 is also positioned on the substrate 520. The memory 523 may comprise one or more memory dies 514a-d. As illustrated in FIG. 8, the memory 523 may comprise a first, second, third and fourth memory die 514a-d. Alternatively, the memory 523 could comprise, for example, eight memory dies or sixteen memory dies. One nonlimiting example of a memory die 412 is provided in FIG. 4.

The controller 516 and memory 523 are in electrical communication through a data bus 818. As illustrated in FIG. 8, the data bus 818 comprises a first and a second portion of a transmission line 819a-b, a discrete inductor 822, a memory terminal 513, and a plurality of wire bonds 512a-c. The transmission line 819a-b comprises a communication channel positioned on the substrate 520. The transmission line 819a-b may be made of a highly conductive material, such as copper. The transmission line 819a-b may be positioned on the substrate 520 using an etching and/or deposition process.

A first inductor terminal 822a is in electrical communication and coupled with the memory terminal 513 (and, in turn, is coupled with the first through fourth memory die terminals 513a-d) via the first portion of the transmission channel 819a. A second inductor terminal 822b is in electrical communication and coupled with a controller terminal 517 via a second portion of the transmission line 819b.

The discrete inductor 822 is any discrete (separately manufactured) electric or electronic circuit or component that possesses inductance. For example, the discrete inductor 822 may comprise, by way of example only, one or more air core inductors, ferromagnetic or iron core inductors, ferrite core inductors, toroidal core inductors, bobbin-based inductors, or multi-layer inductors. As indicated previously, the discrete inductor 822 mitigates or eliminates reflection within the data bus 818 without dissipating power. This is achieved through a reduction in the reflection coefficient.

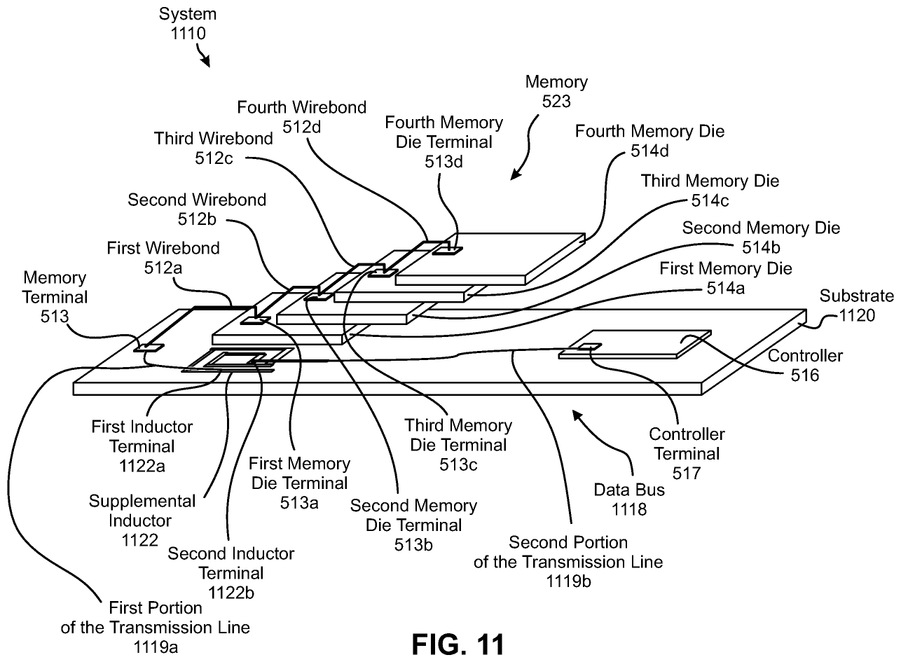

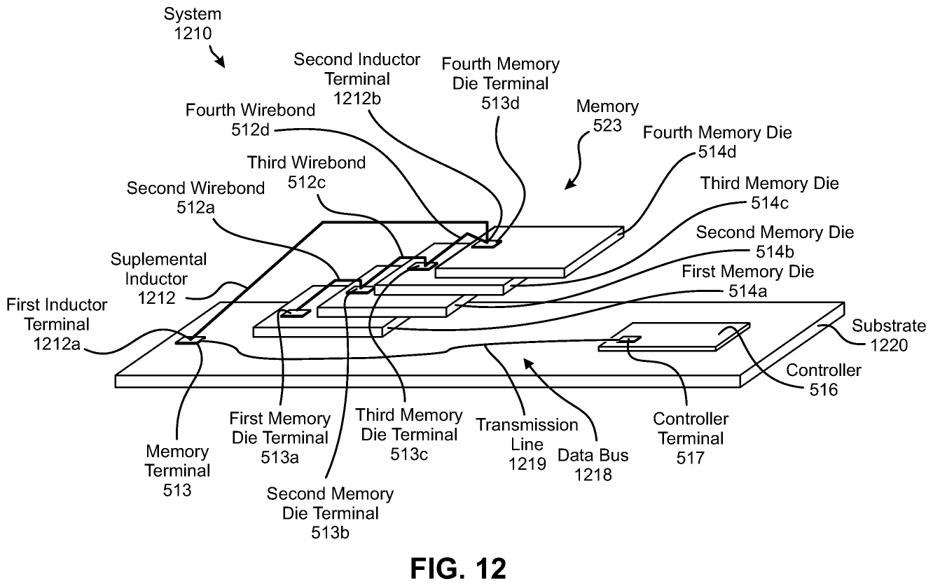

As used herein the term “supplemental inductor” encompasses any component, feature and/or modification that provides increased inductance in a particular system. For example, the addition of inductance to a conventional system, such as the system 510 illustrated in FIGS. 5-6, comprises “supplemental inductance.” In one embodiment, a supplemental inductor is positioned proximate (e.g., within 1 mm of) a juncture between a transmission line and wire bond structure and/or within the wire bond structure. The supplemental inductor, for example, may comprise a discrete inductor 822 (discussed in connection with FIG. 8), a monolithic inductor 1122 (discussed in connection with FIG. 11) or a wire bond inductor 1212 (discussed in connection with FIG. 12).

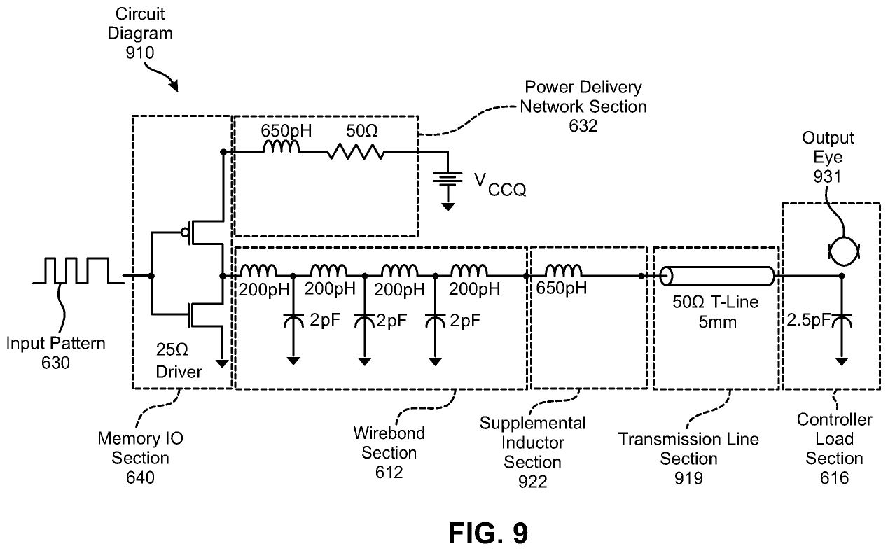

FIG. 9 is one embodiment of a circuit diagram 910 of the system 810 illustrated in FIG. 8. As illustrated, the circuit diagram 910 may comprise a memory input/output section 640, wire bond section 612, a supplemental inductor section 922, a transmission line section 919, a controller load section 616 and a power delivery network section 632. The memory input/output section 640 may comprise, for example, a 25 ohm (S2) memory driver. As illustrated, each wire bond 512a-d represented in the wire bond section 612 comprises 200 pH of inductance, while each memory pin cap comprises 2 pF of capacitance. The transmission line section 619 may, for example, comprise 50 ohms of impedance for a transmission line 519 that is 5 mm in length. The controller load section 616 indicates that a controller pin cap has 2.5 pF of capacitance. The power delivery network section 632 comprises a capacitor of 650 pH and serially coupled a resistor of 50 ohms. A voltage level provided by the system 810 is represented by V.

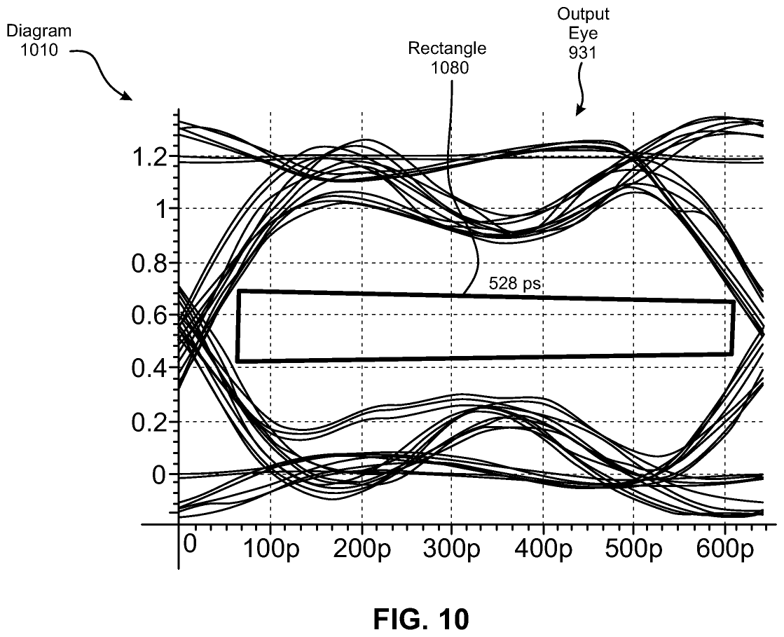

The circuit diagram 910 of FIG. 9 differs from the circuit diagram 610 of FIG. 6 with the inclusion of a supplemental inductor section 922 representing a discrete inductor 822, which is illustrated in FIG. 8. As illustrated in FIG. 9, the discrete inductor 822 may possess 650 pH of inductance and is positioned between the transmission line section 919 in the wire bond section 612 in the diagram 910. An output eye 931 is generated by the system 810 in response to the input pattern 630, as will be discussed further in connection with FIG. 10. It should be noted that the specific components provided in FIG. 9 are merely illustrative and not limiting of the claimed subject matter, as is the case with all figures included in this application.

FIG. 10 is a diagram 1010 of a simulation of an output eye 931 based on the assumptions of the circuit diagram 910 of FIG. 9 with a data rate at 1600 Mbps (800 MHz). The output eye 931, also referred to as an eye pattern, represents an oscilloscope display of the output eye 931 generated by the system 810. The vertical axis represents power (with “1” representing a binary one and “0” representing a binary zero), while the horizontal axis represents time in picoseconds. As illustrated in diagram 1010, the output eye 931 is substantially un-occluded by reflection. A rectangle 1080 represented in the diagram 1010 shows the valid length of the output eye 631 of 528 ps, which is almost twice as large as the output eye 631 shown in FIG. 7. Accordingly, the addition of a supplemental inductor 822 to the data bus 818 substantially mitigates reflection.

FIG. 11 comprises a block diagram illustrating a system 1110 that is analogous to the system 810 illustrated in FIG. 8. The system 1110 includes many of the same components as the system 810 with the exception that a supplemental inductor 1122 comprises a monolithic inductor 1122 and no discrete inductor 822 is included in the system 1110. For the sake of brevity, the common components will not be described in detail, but will be recited briefly below. The system 1110 comprises a substrate 1120 having a controller 516 and a memory 523 positioned thereon. The memory 523 may comprise a plurality of memory dies, such as the four memory dies 514a-d illustrated in FIG. 11. The controller 516 communicates with the memory 523 employing a data bus 1118. As shown in FIG. 11, the data bus 518 comprises a first and second portion of a transmission line 1119a-b, a monolithic inductor 1122, a memory terminal 513, a plurality of wire bonds 512a-d and memory die terminals 513a-d.

A first inductor terminal 1122a is in electrical communication and directly coupled with the memory terminal 513 (and, in turn, is coupled with the first through fourth memory die terminals 513a-d) via the first portion of the transmission channel 1119a. A second inductor terminal 1122b is in electrical communication and coupled with a controller terminal 517 via a second portion of the transmission line 1119b.

The monolithic inductor 1122 is an inductor that formed onto the substrate 1120 using, for example, etching and/or deposition processes. The monolithic inductor 1122, as illustrated, may comprise a number of coils formed in the substrate 1120 to produce inductance during operation. The monolithic inductor 1122 serves the same purpose as the discrete inductor 822 of FIG. 8. The monolithic inductor 1122, however, has the advantage of no added cost or minimal cost in that the monolithic inductor 1122 may be integrally formed with the transmission line 1119a-b. The monolithic inductor 1122 will require more real estate on the substrate 1120 than the discrete inductor 822.

FIG. 12 comprises a block diagram illustrating a system 1210 that is analogous to the system 1110 illustrated in FIG. 11. The system 1210 includes many of the same components as the system 1110 with the exception that a supplemental inductor 1212 comprises a wire bond inductor 1212 and no a monolithic inductor 1122 is included in the system 1210. For the sake of brevity, the common components will not be described in detail but will be recited briefly below. The system 1210 comprises a substrate 1220 having a controller 516 and memory 523 positioned thereon. The memory 523 may comprise a plurality of memory dies, such as the four memory dies 514a-d illustrated in FIG. 11. As illustrated in FIG. 12, the memory dies 514a-d are arranged in a stack extending away from the substrate 1220. The plurality of memory dies 514a-d include a memory die 514d most remote relative to the substrate 1220. As used herein, the term “stacked” or “stack,” refers to a group of items with an initial item closest to the reference point and each subsequent item being positioned consecutively farther apart from the reference point (e.g., farther apart from the substrate 1220).

The controller 516 communicates with the memory 523 employing a data bus 1218, which comprises a transmission line 1219, a memory terminal 513, and a plurality of wire bonds 1212, 512a-d. In the embodiment illustrated in FIG. 12, the data bus 1218 is coupled serially to the memory dies 513a-d and is coupled first to the fourth memory die 514d (i.e., the data bus 1218 is coupled to the most remote memory die 514d before it is connected to the other memory dies 514a-c).

Thus, while the system 1210 lacks a discrete inductor 822 or a monolithic inductor 1122 of FIGS. 8 and 11, the system 1210 comprises a wire bond inductor 1212. The wire bond inductor 1212 comprises an elongate wire bond, signifying that the wire bond 1212 that comprises a wire bond inductor 1212 is longer than the remaining wire bonds 512b-d. Thus, as utilized herein, the term “wire bond inductor” comprises a wire bond that is longer than other wire bonds used within the system to communicate with or between memory dies or, alternatively, comprises a wire bond that is of sufficient length to mitigate reflection and open a corresponding output eye to a desired or target level. Thus, the elongate wire bond inductor 1212 possesses greater inductance than the other wire bonds 512b-d, thereby reducing reflection. In an alternative embodiment, the elongate wire bond inductor 1212 is connected to either the first, second, or third memory die 514a-c.

As illustrated in FIG. 12, a first inductor terminal 1212a of the wire bond inductor 1212 is coupled to the controller terminal 517, and the second inductor terminal 1212b of the wire bond inductor 1212 is coupled to the fourth memory die terminal 513d of the fourth memory die 514d (i.e., most remote memory die 514d). In an alternative embodiment, the elongate wire bond inductor 1212 is connected to either the first, second, or third memory die 514a-c.

The wire bond inductor 1212 may be advantageous over the discrete inductor 822 and monolithic inductor 1122 in that it occupies no additional space on the substrate 1220. Furthermore, the wire bond inductor 1212 is less expensive than the discrete inductor 822.

The characteristic impedance of a transmission line (such as the transmission line 1219 shown in FIG. 12) may be calculated utilizing Equation 1, in which Zo signifies the characteristic impedance of the transmission line, the L signifies the inductance per unit length of the line, and C signifies the capacitance per unit length of the line.

$${Z}_{0} = \sqrt{\frac{L}{C}} \qquad Equation 1$$

The reflection coefficient of an impedance discontinuity (e.g., between a transmission line 1219 and a wire bond structure) may be calculated utilizing Equation 2, in which τ signifies the reflection coefficient, and ZL signifies a load impedance (e.g., the impedance of a transmission line 1219) and Zs signifies a source impedance (e.g., the impedance of a wire bond structure). As noted above, the wire bond structure comprises the wire bonds 512a-d and the associated pin caps.

$$τ = \frac{{Z}_{L} - {Z}_{S}}{{Z}_{L} + {Z}_{S}} \qquad Equation 2$$

In a conventional design (e.g., an example design illustrated in FIGS. 5 and 6), the characteristic impedance of the wire bond structure may be computed, as illustrated below in Equation 3 (employing the general formula set forth in Equation 1).

$${Z}_{0} = \sqrt{\frac{200}{2}} = 10 Ω \qquad Equation 3$$

In such a conventional system, the reflection coefficient between the transmission line 519 and the wire bond structure may be calculated as illustrated below in Equation 4 (employing the general formula set forth in Equation 2).

$$τ = \frac{50 - 10}{50 + 10} = 0.67 \qquad Equation 4$$

However, when inductive compensation is employed (through use of a supplemental inductor 1212, as illustrated in FIG. 12), the characteristic impedance of the wire bond structure may be calculated as illustrated below in Equation 5 (employing the general formula set forth in Equation 1) if the added length of the wire bond inductor 1212 increases inductance by 650 pH.

$$Z 0 = \sqrt{\frac{200 + 650}{2}} = 21 Ω \qquad Equation 5$$

Thus, when inductive compensation is employed, the reflection coefficient between the transmission line 1219 may be calculated as illustrated below in Equation 6 (employing the general formula set forth in Equation 2).

$$τ = \frac{50 - 21}{50 + 21} = 0.40 \qquad Equation 6$$

Thus, the reflection coefficient is reduced significantly—from 0.67 to 0.40—in the example provided in connection with FIG. 12.

An embodiment of an apparatus is disclosed. The apparatus comprises memory having at least one memory die. The apparatus further comprises a memory controller, a data bus coupled to the controller and the memory. A supplemental inductor is within the data bus.

The supplemental inductor may comprise a wire bond inductor, a discrete inductor or a monolithic inductor. In one embodiment, a transmission speed for data transmitted between the controller and the memory in the data bus is at least 1200 Mbps.

The memory may comprise a plurality of memory dies positioned on a substrate. The plurality of memory dies may be arranged in a stack extending away from the substrate. Thus, the plurality of memory dies may comprise a memory die most remote relative to the substrate, and the plurality of memory dies may be serially coupled to the data bus. In one embodiment, the data bus is coupled first to the most remote memory die.

An embodiment of a nonvolatile storage device is also disclosed. The storage device comprises a plurality of coupled memory dies having a memory terminal, and a memory controller comprising a controller terminal. The device may further comprise a wire bond inductor including a first inductor terminal and a second inductor terminal. The first inductor terminal is coupled to the controller terminal, and the second inductor terminal is coupled to the memory terminal.

The device may further comprise a substrate, and the plurality of coupled memory dies may be disposed on the substrate. In one embodiment, the plurality of coupled memory dies are arranged in a stack extending away from the substrate.

The plurality of coupled memory dies may comprise a memory die most remote relative to the substrate with wire bond inductor coupled to the most remote memory die.

In one embodiment, a transmission speed for data transmitted between the memory controller and the memory dies is at least 1200 Mbps.

The plurality of coupled memory dies may be serially coupled and may be serially coupled employing wire bonds.

An embodiment of an embedded system is also disclosed. The system comprises NAND flash memory including a plurality of memory dies and a memory die terminal, and a memory controller for controlling the NAND flash memory with the memory controller comprising a controller terminal. A data bus is coupled to the controller terminal and the memory die terminal. An elongate wire bond inductor comprises a portion of the data bus. The system also comprises a substrate with the NAND flash memory and memory controller being positioned on the substrate.

In one embodiment, the plurality of memory dies are arranged in a stack extending away from the substrate and are serially coupled. The plurality of memory dies may comprise a memory die most remote relative to the substrate with the data bus being coupled first to the most remote memory die.

A transmission speed for data transmitted between the memory controller and the NAND flash memory along the data bus, in one embodiment, is at least 1200 Mbps.

The plurality of coupled memory dies may be serially coupled, and may be serially coupled employing wire bonds. The present disclosure can be embodied in other specific forms without departing from its spirit or essential characteristics.

The described embodiments are to be considered in all respects only as illustrative and not restrictive. The scope of the disclosure is, therefore, indicated by the appended claims rather than by the foregoing description. All changes which come within the meaning and range of equivalency of the claims are to be embraced within their scope.

What is claimed is:

1. An apparatus comprising:
memory comprising at least one memory die;
a memory controller;
a data bus coupled to the controller and the memory; and
a supplemental inductor within the data bus.

2. The apparatus of claim 1, wherein the supplemental inductor comprises a wire bond inductor.

3. The apparatus of claim 1, wherein the supplemental inductor comprises a discrete inductor.

4. The apparatus of claim 1, wherein the supplemental inductor comprises a monolithic inductor.

5. The apparatus of claim 1, wherein a transmission speed for data transmitted between the controller and the memory in the data bus is at least 1200 Mbps.

6. The apparatus of claim 1, wherein the memory comprises a plurality of memory dies positioned on a substrate.

7. The apparatus of claim 6, wherein the plurality of memory dies are arranged in a stack extending away from the substrate, the plurality of memory dies comprising memory die most remote relative to the substrate, the plurality of memory dies are serially coupled to the data bus, and wherein the data bus is coupled first to the most remote memory die.

8. A nonvolatile storage device comprising:
a plurality of coupled memory dies comprising a memory terminal;
a memory controller comprising a controller terminal; and
a wire bond inductor comprising a first inductor terminal and a second inductor terminal, wherein the first inductor terminal is coupled to the controller terminal, and the second inductor terminal is coupled to the memory terminal.

9. The device of claim 8, further comprising a substrate, wherein the plurality of coupled memory dies are disposed on the substrate.

10. The device of claim 9, wherein the plurality of coupled memory dies are arranged in a stack extending away from the substrate.

11. The device of claim 10, wherein the plurality of coupled memory dies comprise a memory die most remote relative to the substrate, the wire bond inductor coupled to the most remote memory die.

12. The device of claim 8, wherein a transmission speed for data transmitted between the memory controller and the memory dies is at least 1200 Mbps.

13. The device of claim 8, wherein the plurality of coupled memory dies are serially coupled.

14. The device of claim 8, wherein the plurality of coupled memory dies are serially coupled employing wire bonds.

15. An embedded system comprising:
NAND flash memory comprising a plurality of memory dies and a memory die terminal;
a memory controller for controlling the NAND flash memory, the memory controller comprising a controller terminal;
a data bus coupled to the controller terminal and the memory die terminal;
an elongate wire bond inductor comprising a portion of the data bus; and
a substrate, wherein the NAND flash memory and memory controller are positioned on the substrate.

16. The system of claim 15, wherein the plurality of memory dies are arranged in a stack extending away from the substrate and are serially coupled.

17. The system of claim 16, wherein the plurality of memory dies comprise a memory die most remote relative to the substrate, the data bus is coupled first to the most remote memory die.

18. The system of claim 15, wherein a transmission speed for data transmitted between the memory controller and the NAND flash memory along the data bus is at least 1200 Mbps.

19. The system of claim 15, wherein the plurality of coupled memory dies are serially coupled.

20. The device of claim 8, wherein the plurality of coupled memory dies are serially coupled employing wire bonds.
